(19) United States
(12) Patent Application Publication
(10) Pub. No.: US 2025/0191818 A1
(43) Pub. Date: Jun. 12, 2025

(54) CO-SPUTTERING RARE EARTH ROTATING TARGET MATERIAL, AND PREPARATION METHOD, AND APPLICATION METHOD THEREFOR

(71) Applicants: GRIREM ADVANCED MATERIALS CO., LTD., Beijing (CN); GRIREM HI-TECH CO., LTD., Langfang (CN)

(72) Inventors: Zhiqiang WANG, Beijing (CN); Dehong CHEN, Beijing (CN); Jiamin ZHONG, Beijing (CN); Zongan LI, Beijing (CN); Hongbo YANG, Beijing (CN); Jun CHENG, Beijing (CN); Siming PANG, Beijing (CN); Bingzheng YANG, Beijing (CN); Shuang WANG, Beijing (CN); Yanling ZHANG, Beijing (CN); Xiaoqiang ZHANG, Beijing (CN); Dezhong LIU, Beijing (CN); Liguo HAN, Beijing (CN)

(73) Assignees: GRIREM ADVANCED MATERIALS CO., LTD., Beijing (CN); GRIREM HI-TECH CO., LTD., Langfang (CN)

(21) Appl. No.: 19/057,066

(22) Filed: Feb. 19, 2025

Related U.S. Application Data
(63) Continuation of application No. PCT/CN2023/116521, filed on Sep. 1, 2023.

(30) Foreign Application Priority Data
Sep. 7, 2022 (CN) 202211099776.4

(51) Int. Cl. H01F 1/053; C23C 14/14; C23C 14/34

(52) U.S. Cl. CPC H01F 1/053; C23C 14/14; C23C 14/3414

(57) ABSTRACT

Disclosed are a co-sputtering rare earth rotating target material, and a preparation method and an application method therefor. The co-sputtering rare earth rotating target material includes two sections of end target tubes arranged at an axial end of the target material, and a plurality of sections of rare earth target tubes and a plurality of sections of co-sputtering target tubes which are arranged between the two sections of end target tubes and with a target material along an axial middle region, wherein the plurality of sections of rare earth target tubes are spaced apart from the plurality of sections of co-sputtering target tubes, and the target tubes are mutually assembled via welding; and the co-sputtering target tubes are selected from at least one of aluminum, copper, nickel, iron and praseodymium target tubes, and the end target tubes are non-rare earth target tubes or rare earth target tubes.

### CROSS-REFERENCE TO RELATED APPLICATIONS

This application is a continuation of International Application No. PCT/CN2023/116522, filed on Sep. 1, 2023, which claims priority to Chinese Patent Application No. 202211099977.4, filed on Sep. 7, 2022. The disclosures of the above-mentioned applications are hereby incorporated by reference in their entireties.

### TECHNICAL FIELD

Embodiments of the present application relate to the technical field of magnetic materials, and more particularly, to a co-sputtering rare earth rotating target material, a preparation method, and an application method therefor.

### BACKGROUND ART

Rare earth target materials have been increasingly used in the fields of grain boundary diffusion of magnetic coating, storage, and electronic information. Magnetron sputtering coating is one of the main ways of grain boundary diffusion of neodymium-iron-boron (NdFeB). Single target material step-wised sputtering and independent target material sputtering at the same time can be used. However, the sputtering efficiency of single target material step-wised sputtering is low, and the sputtering parameters of independent target material sputtering at the same time are difficult to control. In addition, the utilization rate of rare earth metal and alloy planar target material is generally 30-50%, and the utilization rate of the target material is low.

### SUMMARY

Based on the above-mentioned situation of the prior art, it is an objective of the embodiments of the present application to provide a co-sputtering rare earth rotating target material, a preparation method and an application method therefor, that achieve the purpose of improving the grain boundary diffusion and optimizing the performance of a magnet by simultaneously sputtering rare earth elements and co-sputtering elements on the surface of NdFeB by simultaneously sputtering a multiple sections of rotating target materials on a coating production line.

To achieve the above objectives, according to one aspect of the present application, provided is a co-sputtering rare earth rotating target material, comprising a back tube and a plurality of sections of target tubes welded to the outside of the back tube; wherein the back tube and the plurality of sections of target tubes welded to the outside of the back tube are concentric cylindrical structures;
the plurality of sections of target tubes welded to the outside of the back tube comprise two sections of end target tubes arranged at an axial end of the target material, and a plurality of sections of rare earth target tubes and a plurality of sections of co-sputtering target tubes which are arranged between the two sections of end target tubes and with a target material along an axial middle region; the plurality of sections of rare earth target tubes are spaced apart from the plurality of sections of co-sputtering target tubes, and the target tubes are mutually assembled by means of welding; and
the co-sputtering target tubes are selected from at least one of aluminum, copper, nickel, iron, and praseodymium target tubes, and the end target tubes are non-rare earth target tubes or rare earth target tubes.

Further, the rare earth target tube includes a rotating target tube selected from terbium, dysprosium, holmium, and gadolinium;
preferably, the rare earth target tube comprises a rotating target tube selected from terbium and dysprosium.

Further, the length of the end target tube is 20-35 mm, the lengths of both the rare earth target tube and the co-sputtering target tube are less than or equal to 300 mm, and the length ratio of the rare earth target tube and the co-sputtering target tube arranged in the middle region is 1.3-20.

Further, a clearance d is left between the assembled mutually target tubes, and the value of the clearance d is 0.1 mm≤d≤0.5 mm.

Further, the co-sputtering target tube is an aluminum target tube or a copper target tube; when the co-sputtering target tube is an aluminum target tube, the length ratio of the rare earth target tube to the co-sputtering target tube arranged in the middle region is 1.8-3.0; when the co-sputtering target tube is a copper target tube, the length ratio of the rare earth target tube to the co-sputtering target tube arranged in the middle region is 6.0-10.0.

Further, the outer diameters of two rare earth target tubes adjacent to the end target tubes at both ends of the target material are reduced from an outer diameter OD2 to an outer diameter OD3 from the direction of both ends of the target material to the direction of the middle region, and the outer diameter OD2 is equal to the outer diameter OD1 of the end target tube.

According to a second aspect of the present application, provided is a preparation method for a rare earth rotating target material as described in the first aspect of the present application, comprising the following steps:
assembling two sections of end target tubes, a plurality of sections of rare earth target tubes, and a plurality of sections of co-sputtering target tubes, wherein the two sections of end target tubes are arranged at two ends of the target material along the axial direction; the plurality of sections of rare earth target tubes are spaced apart from the plurality of sections of co-sputtering target tubes in the middle region of the target material along the axial direction; and the plurality of sections of rare earth target tubes are spaced apart from the plurality of sections of co-sputtering target tubes;
assembling each target tube by welding; and
welding the assembled target tubes and the back tube.

According to a third aspect of the present application, provided is a method for co-sputtering using the rare earth rotating target material as described in the first aspect of the present application, comprising the following steps:
arranging the rare earth rotating target material and a magnet on a coating production line;
performing vacuum pumping, pre-sputtering, and then sputtering; and
subjecting the magnet to thermal and temper treatments.

Further, the thermal treatment temperature is 600-950° C.; preferably, the thermal treatment temperature is 800-900° C.; and
the thermal treatment time is 5-10 hours.

Further, the temper treatment temperature is 400-600° C. and the temper treatment time is 2-6 hours.

In summary, the embodiments of the present application provide a co-sputtering rare earth rotating target material, a preparation method and an application method therefor. The co-sputtering rare earth rotating target material includes two sections of end target tubes arranged at an axial end of the target material, and a plurality of sections of rare earth target tubes and a plurality of sections of co-sputtering target tubes which are arranged between the two sections of end target tubes and with a target material along an axial middle region. The plurality of sections of rare earth target tubes are spaced apart from the plurality of sections of co-sputtering target tubes, and the target tubes are mutually assembled by means of welding. The co-sputtering target tubes are selected from at least one of aluminum, copper, nickel, iron, and praseodymium target tubes, and the end target tubes are non-rare earth target tubes or rare earth target tubes. According to the technical solution provided in the embodiments of the present application, a rare earth target tube is combined with a target tube of co-sputtering elements such as aluminum and copper on the same rotating target material, and multiple rotating target materials are simultaneously sputtered on a coating production line so that rare earth such as terbium and dysprosium and co-sputtering elements simultaneously adhere to the surface of NdFeB, which is helpful for the subsequent grain boundary diffusion. The beneficial technical effects of shortening the grain boundary diffusion time and reducing the diffusion temperature can be achieved while the utilization rate and the sputtering efficiency of the rare earth target material are improved.

### BRIEF DESCRIPTION OF THE DRAWINGS

FIG. 1 is a schematic diagram of the overall structure of a co-sputtering rare earth rotating target material provided in an embodiment of the present application.

FIG. 2 is a flowchart of the preparation method of a co-sputtering rare earth rotating target material provided in an embodiment of the present application.

FIG. 3 is a flowchart of a preparation method for co-sputtering using a rare earth rotating target material provided in an embodiment of the present application.

### DETAILED DESCRIPTION OF THE EMBODIMENTS

In order to make the objective, technical solution, and advantages of the present application clearer, the following is a detailed explanation of the present application, combined with specific examples and referring to the accompanying drawings. It is to be understood that this description is made only by way of example and not as a limitation on the scope of the application. Further, in the following description, descriptions of publicly known structures and techniques are omitted to avoid unnecessarily confusing the concepts of the present application.

It should be noted that unless otherwise defined, technical or scientific terms used in one or more embodiments of the present application shall have the ordinary meaning as understood by one of ordinary skill in the art to which the present disclosure belongs. The use of “first”, “second”, and similar terms in one or more embodiments of the present disclosure does not denote any order, quantity, or importance, but rather is used to distinguish one element from another. The word “comprising” or “comprises”, and the like, means that the elements or items preceding the word encompass the elements or items listed after the word and equivalents therefor, but do not exclude other elements or items. Terms such as “connected” or “attached” are not limited to physical or mechanical connections, but may include electrical connections, whether direct or indirect. Terms such as “up”, “down”, “left”, “right”, etc. are only used to indicate a relative positional relationship. When the absolute position of the described objective changes, the relative positional relationship may also change accordingly.

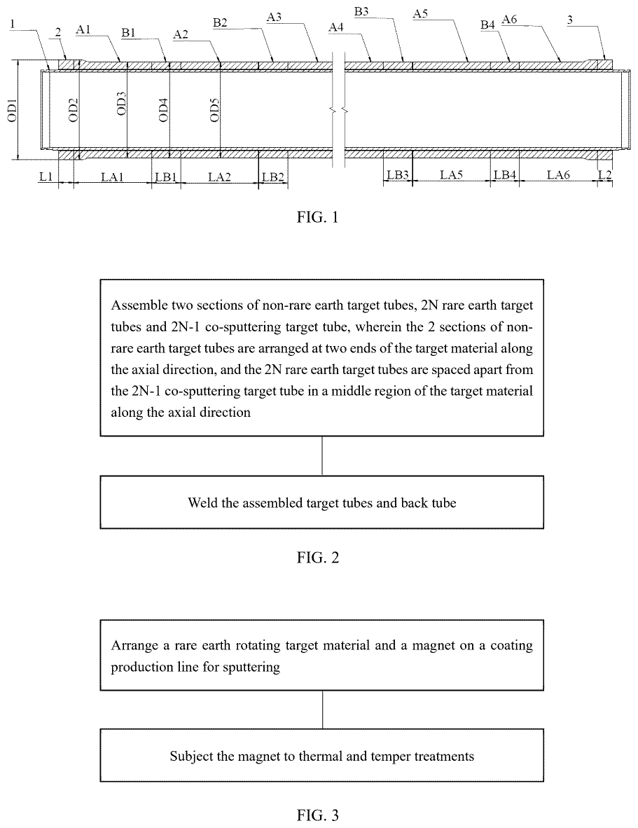

Below, the technical solution of the present application will be described in detail with reference to the accompanying drawings. According to an embodiment of the present application, provided is a co-sputtering rare earth rotating target material. FIG. 1 shows a schematic diagram of the overall structure of the co-sputtering rare earth rotating target material. As shown in FIG. 1, the rare earth rotating target material includes a back tube 1 and the plurality of sections of target tubes welded to the outside of the back tube. The back tube 1 and the plurality of sections of target tubes welded to the outside of the back tube are concentric cylindrical structures. The plurality of sections of target tubes welded to the outside of the back tube comprise two sections of end target tubes 2 and 3 arranged at an axial end of the target material, and a plurality of sections of rare earth target tubes Ai (i=1, 2, 3 . . . ) and a plurality of sections of co-sputtering target tubes Bi (i=1, 2, 3 . . . ) arranged in an axial middle region of the target material between the two sections of end target tubes; the plurality of sections of rare earth target tubes Ai (i=1, 2, 3 . . . ) are spaced apart from the plurality of sections of co-sputtering target tubes Bi (i=1, 2, 3 . . . ), and the target tubes are mutually assembled by means of welding. The welding is a low-temperature welding, and the welding can be performed using a low-temperature alloy solder such as indium and tin. During welding, there shall be a clearance d between the mutually assembled target tubes, and the minimum clearance shall be related to the expansion coefficient of the material, and the value of the clearance d shall be 0.1 mm≤d≤0.5 mm. The end target tubes are non-rare earth target tubes or rare earth target tubes.

FIG. 1 illustrates a co-sputtering rare earth rotating target material of 6 rare earth target tubes A1-A6 and 5 co-sputtering target tubes B1-B5 as an example. A person skilled in the art would also have been able to select the number of target tubes according to actual needs and satisfy the requirement of arranging the rare earth target tubes spaced apart from the co-sputtering target tubes, which should not be taken as a restriction on the technical solution of the present application.

Wherein the co-sputtering target tubes are selected from at least one of aluminum, copper, nickel, iron and praseodymium target tubes, preferably the co-sputtering target tube is an aluminum target tube or a copper target tube. The end target tubes are stainless-steel target tubes or titanium target tubes. The rare earth target tube comprises a rotating target tube selected from terbium, dysprosium, holmium, and gadolinium; preferably, the rare earth target tube is a rotating target tube selected from terbium and dysprosium.

The length of the individual rare earth target tube is set as L_{Ai}, and the length of the individual co-sputtering target tube is set as L_{Bi}. The length ratio of the rare earth target tube to the co-sputtering target tube arranged in the middle region is 1.3-20, namely, the value range of ΣL_{Ai}/ΣL_{Bi} is 1.3-20. when the co-sputtering target tube is an aluminum target tube, the length ratio of the rare earth target tube to the co-sputtering target tube arranged in the middle region (i.e., ΣL_{Ai}/ΣL_{Bi}) is 1.8-3.0; when the co-sputtering target tube is a copper target tube, the length ratio of the rare earth target tube to the co-sputtering target tube arranged in the middle region (i.e., ΣL_{Ai}/ΣL_{Bi}) is 6.0-10.0.

Further, the outer diameters of two rare earth target tubes adjacent to the end target tubes 2 and 3 at both ends of the target material are reduced from an outer diameter OD2 to an outer diameter OD3 from the direction of both ends of the target material to the direction of the middle region, and the outer diameter OD2 is equal to the outer diameter OD1 of the end target tube. As shown in FIG. 1, the outer diameter of the end target tube 2 and the end target tube 3 at the two ends of the target material is OD1. The outer diameter of the rare earth target tubes A1 and A6 adjacent to the end target tube 2 and the end target tube 3 are in a shape similar to a dog bone. According to the structural characteristics of the magnetic field in the target tube, the magnetic fields at the two ends are slightly larger than that in the middle, so that the target material at the two ends is consumed quickly. By setting the target tube in a special shape (for example, the shape similar to a dog bone at the two ends), the utilization rate of the target material can be improved. The outer diameter of the rest near the two ends is OD2, and the outer diameter near the middle region is OD3, with OD2>OD3, while the outer diameter of the co-sputtering target tubes B1-B5 in the middle region is OD4, and the outer diameter of the other rare earth target tubes A2, A3, A4, and A5 are OD5, with OD3=OD4=OD5.

According to an embodiment of the present application, also provided is a preparation method for a rare earth rotating target material that is the rare earth rotating target material provided by the above-mentioned embodiment of the present application. A flow chart of the method is shown in FIG. 2, the method comprising the following steps:
assembling two sections of end target tubes, a plurality of sections of rare earth target tubes, and a plurality of sections of co-sputtering target tubes, wherein the two sections of end target tubes are arranged at two ends of the target material along the axial direction; the plurality of sections of rare earth target tubes are spaced apart from the plurality of sections of co-sputtering target tubes in the middle region of the target material along the axial direction; and the plurality of sections of rare earth target tubes are spaced apart from the plurality of sections of co-sputtering target tubes;
assembling each target tube by welding; and
welding the assembled target tubes and the back tube.

According to an embodiment of the present application, further provided is a method for co-sputtering using the rare earth rotating target material that is the rare earth rotating target material provided by the above-mentioned embodiment of the present application. A flow chart of the co-sputtering method is shown in FIG. 3, the co-sputtering method comprising the following steps:
arranging the rare earth rotating target material and a magnet such as a neodymium-iron-boron (NeFeB) magnet on a coating production line, wherein in this step, the rare earth rotating target material can be one or more target materials, and in the case of a plurality of the target materials, the targets are arranged in parallel; the power density of the target material is 0.5-6 W/cm², preferably 3-5 W/cm², and the magnet weight gain is controlled at 0.2-0.6%; the power density of the target material is related to the sputtering efficiency; the power is small, the sputtering time is long, and the final effects are the same; the weight gain ratio is primarily to achieve magnet performance or to shorten the time or lower the temperature to achieve performance or on the premise of achieving performance;
subjecting the magnet to thermal and temper treatments, wherein the thermal treatment temperature is 600-950° C.; preferably, the thermal treatment temperature is 800-900° C. and the thermal treatment time is 5-10 hours; the temper temperature is 400-600° C. and the temper time is 2-6 hours.

By co-sputtering using the rare earth rotating target material provided in the examples of the present application, the thermal treatment temperature can be reduced by 50-150° C. compared with the target material without adding a co-sputtering element; at the same thermal treatment temperature, the thermal treatment time can be reduced by 0.5-2 hours, and the utilization rate of the target material can be up to 85% or more; the experimental conditions of reducing the heat diffusion temperature and shortening the diffusion time are simplified and reduced, and the utilization rate of the target material can be improved.

Specific examples and experimental data are given below.

### Example 1

The total length of the rotating target material was 1600 mm. The clearance between two target tubes was 0.25 mm. There was 9 terbium target tubes and 8 aluminum tubes by assembling. The OD1 was 165 mm; the OD2 is 165 mm; the OD3=OD4=OD5=158 mm; L1=L2=30 mm. The material of the end target tubes was stainless steel. Both A1 and A6 exhibited a dog-bone shape. The ratio of ΣL_{Ai}/ΣL_{Bi} was 2.7. Neodymium-iron-boron with a thickness of 6 mm was placed in the coating production line. The power density of the target material was 4 W/cm²; the weight gain ratio of the magnet was 0.4%; the thermal treatment temperature was 900° C.; the thermal treatment time was 10 h; the temper temperature and time were 500° C. and 2 hours, respectively.

### Comparative Example 1

The co-sputtering target tube was a terbium target tube with a weight gain ratio of 0.35%, and the rest of the conditions were the same as in Example 1.

Example 2: the thermal treatment temperature was 850° C., and the rest of the conditions were the same as Example 1.

Example 3: the thermal treatment time was 8 hours, and the rest of the conditions were the same as in Example 1.

Example 4: there were 10 terbium target tubes and 9 aluminum tubes by assembling; the ratio of ΣL_{Ai}/ΣL_{Bi} was 1.8; the thermal treatment temperature was 850° C.; the time was 10 h; and the weight gain ratio was 0.41%. The rest of the conditions were the same as in Example 1.

Comparative Example 2: there were 11 terbium target tubes and 9 aluminum tubes by assembling; the ratio of ΣL_{Ai}/ΣL_{Bi} was 1; the thermal treatment temperature was 850° C.; the time was 10 h; and the weight gain ratio was 0.47%. The rest of the conditions were the same as in Example 1.

Comparative Example 3: there were 11 terbium target tubes and 10 aluminum tubes by assembling; the ratio of ΣL_{Ai}/ΣL_{Bi} was 4; the thermal treatment temperature was 850° C.; the time was 10 h; and the weight gain ratio was 0.38%. The rest of the conditions were the same as in Example 1.

Example 5: the co-sputtering target tube was a copper target tube and there were 11 terbium target tubes and 10 copper tubes by assembling. The ratio of ΣL_{Ai}/ΣL_{Bi} was 10. The rest of the conditions were the same as in Example 2.

Example 6: the co-sputtering target tube was a copper target tube, and there were 12 terbium target tubes and 10 copper tubes by assembling. The ratio of ΣL_{Ai}/ΣL_{Bi} was 6 and a weight gain ratio was 0.41%. The rest of the conditions were the same as in Example 2.

Comparative Example 4: the co-sputtering target tube was a copper target tube, and there were 11 terbium target tubes and 10 copper tubes by assembling. The ratio of ΣL_{Ai}/ΣL_{Bi} was 5 and the weight gain ratio was 0.43%. The rest of the conditions were the same as in Example 2.

Comparative Example 5: the co-sputtering target tube was a copper target tube, and there were 12 terbium target tubes and 10 copper tubes by assembling. The ratio of ΣL_{Ai}/ΣL_{Bi} was 26 and the weight gain ratio was 0.36%. The rest of the conditions were the same as in Example 2.

Example 7: the co-sputtering target tube was a terbium tube+aluminum tube+copper tube. The ratio of ΣL_{Ai}/ΣL_{Bi} was 4.5, and the length ratio of terbium, aluminum and copper tubes was 1:0.38:0.115. The rest of the conditions were the same as in Example 2.

Example 8: the co-sputtering target tube was a dysprosium tube+an aluminum tube. The total length of the rotating target material was 1200 mm. The clearance between two target tubes was 0.25 mm. There were 5 terbium target tubes and 4 aluminum tubes by assembling. The OD1 is 110 mm; the OD2 is 110 mm; the OD3=OD4=OD5=105 mm; the L1=L2=30 mm. The material of the non-rare earth target tube end target tubes is stainless steel. Both A1 and A6 exhibited a dog-bone shape. The ratio of ΣL_{Ai}/ΣL_{Bi} was 1.8 and a weight gain ratio of 0.41%. The rest of the conditions were the same as in Example 2.

Example 9: the co-sputtering target tube was a dysprosium tube+copper tube. The ratio of ΣL_{Ai}/L_{Bi} was 10 and a weight gain ratio was 0.4%. The rest of the conditions were the same as in Example 2.

Comparative Example 6: the sputtering target material was a pure dysprosium target. The weight gain ratio was 0.35%. The rest of the conditions were the same as in Example 2.

Comparative Example 7: LA1 and LA6 do not exhibit a dog-bone shape, with OD2=OD3=165 mm. The thermal treatment temperature was 850° C. The rest of the conditions were the same as in Example 1.

Comparative Example 8: the material of non-rare earth target tubes 2 and 3 was terbium. The thermal treatment temperature was 850° C. The rest of the conditions were the same as Example 1.

Table 1 shows the performance parameter tables of the various examples and comparative examples provided above.

TABLE 1
Table of performance parameters of each example and comparative example

| | | | Length of rare | | | | Aluminum | | | | | |
|---|---|---|---|---|---|---|---|---|---|---|---|---|
| | Rare | Co- | earth target | | | | (copper)/ | | | | | Utilization |
| | earth | sputtering | tube/length of | Material | | Magnet | Magnet | Power | Thermal | Thermal | Coer- | rate of the |
| | target | target | co-sputtering | for the | Dog- | weight | weight | density/ | treatment | treatment | civity/ | target |
| No. | tube | tube | target tube | two ends | bone | gain | gain | W/cm² | temperature/° C. | time/h | KOe | material |
| Ex. 1 | Tb | Al | 2.7 | Stainless | Yes | 0.40% | 10% | 4 | 900 | 10 | 41.8 | 88% |
| | | | | steel | | | | | | | | |
| Comp. | Tb | None | / | Stainless | Yes | 0.35% | 0% | 4 | 900 | 10 | 41 | 88% |
| Ex. 1 | | | | steel | | | | | | | | |
| Ex. 2 | Tb | Al | 2.7 | Stainless | Yes | 0.40% | 10% | 4 | 850 | 10 | 41.5 | 88% |
| | | | | steel | | | | | | | | |
| Ex. 3 | Tb | Al | 2.7 | Stainless | Yes | 0.40% | 10% | 4 | 900 | 8 | 41.4 | 88% |
| | | | | steel | | | | | | | | |
| Ex. 4 | Tb | Al | 1.8 | Stainless | Yes | 0.41% | 15% | 4 | 850 | 10 | 41.2 | 88% |
| | | | | steel | | | | | | | | |
| Comp | Tb | Al | 1 | Stainless | Yes | 0.47 | 25% | 4 | 850 | 10 | 38.0 | 88% |
| Ex. 2 | | | | steel | | | | | | | | |
| Comp. | Tb | Al | 4 | Stainless | Yes | 0.38% | 7.6% | 4 | 850 | 10 | 39.0 | 88% |
| Ex. 3 | | | | steel | | | | | | | | |
| Ex. 5 | Tb | Cu | 10 | Stainless | Yes | 0.40% | 10% | 4 | 850 | 10 | 41.2 | 88% |
| | | | | steel | | | | | | | | |
| Ex. 6 | Tb | Cu | 6 | Stainless | Yes | 0.41% | 15% | 4 | 850 | 10 | 41.1 | 88% |
| | | | | steel | | | | | | | | |
| Comp. | Tb | Cu | 5 | Stainless | Yes | 0.43% | 18% | 4 | 850 | 10 | 39.5 | 88% |
| Ex. 4 | | | | steel | | | | | | | | |
| Comp. | Tb | Cu | 26 | Stainless | Yes | 0.36% | 4% | 4 | 850 | 10 | 39.8 | 88% |
| Ex. 5 | | | | steel | | | | | | | | |
| Ex. 7 | Tb | Cu + Al | 4.5 | Stainless | Yes | 0.40% | 5% for | 4 | 850 | 10 | 41.7 | 88% |
| | | | (1:0.38:0.115) | steel | | | each of | | | | | |
| | | | | | | | Al and | | | | | |
| | | | | | | | Cu | | | | | |
| Ex. 8 | Dy | Al | 1.8 | Stainless | Yes | 0.41% | 15% | 4 | 850 | 10 | 34 | 88% |
| | | | | steel | | | | | | | | |
| Ex. 9 | Dy | Cu | 10 | Stainless | Yes | 0.4% | 10% | 4 | 850 | 10 | 33.8 | 88% |
| | | | | steel | | | | | | | | |
| Comp. | Dy | None | / | Stainless | Yes | 0.35% | 0% | 4 | 850 | 10 | 33.5 | 88% |
| Ex. 6 | | | | steel | | | | | | | | |
| Comp. | Tb | Al | 2.7 | Stainless | None | 0.40% | 10% | 4 | 850 | 10 | 41.5 | 85% |
| Ex. 7 | | | | steel | | | | | | | | |
| Comp. | Tb | Al | 2.7 | None | Yes | 0.40% | 10% | 4 | 850 | 10 | 41.5 | 82% |
| Ex. 8 | | | | | | | | | | | | |
| Original | | | | | | | | | | | 32 | / |
| sample | | | | | | | | | | | | |

It can be seen from the above-mentioned data in Table 1 that the co-sputtering rare earth rotating target material provided in the embodiments of the present application can simultaneously achieve the co-sputtering of the rare earth and the co-sputtering elements on one target material by controlling the length ratio of the rare earth target tube and the co-sputtering target tube and controlling the structure of the target material, improving the sputtering efficiency, shortening or decreasing the diffusion temperature, improving the grain boundary diffusion and optimizing the magnet performance.

Firstly, when the terbium content of the magnet is increased by the same content, adding a certain content of aluminum and copper is beneficial to optimize the magnet performance. For example, when the terbium length/aluminum length=2.7, the coercivity after adding aluminum is increased by 0.8 KOe compared with that after adding pure terbium; when the terbium length/copper length=10, the coercivity after adding copper is increased by 0.3 KOe compared with that after adding pure terbium; when the terbium length/aluminum length/copper length=1:0. 38:0.115, the coercivity after adding aluminum and copper is increased by 0.7 KOe compared with that after adding pure terbium; when the dysprosium length/aluminum length=1.8, the coercivity after adding aluminum is increased by 0.5 KOe compared with adding pure terbium.

Secondly, compared with adding pure terbium, adding proper amount of co-sputtering element can reduce the diffusion temperature or shorten the diffusion time under the same coercivity. For example, under the conditions of adding co-sputtering element at a thermal treatment temperature of 850° C. for a thermal treatment time of 10 h, at a thermal treatment temperature of 900° C. for a thermal treatment time of 8 h, and adding pure terbium at a thermal treatment temperature of 900° C. for a thermal treatment time of 10 h, the coercivity of the magnet can reach above 41 KOe.

Lastly, replacing the end target tubes at both ends of the target material, or processing the target tubes A1 and A6 near both ends of the target material into the dog bones, is beneficial to improve the utilization rate of the target material, which can be up to 88% when both are used simultaneously.

In summary, the embodiments of the present application relate to a co-sputtering rare earth rotating target material, a preparation method and an application method therefor. The co-sputtering rare earth rotating target material includes two sections of end target tubes arranged at an axial end of the target material, and a plurality of sections of rare earth target tubes and a plurality of sections of co-sputtering target tubes which are arranged between the two sections of end target tubes and with a target material along an axial middle region. The plurality of sections of rare earth target tubes are spaced apart from the plurality of sections of co-sputtering target tubes, and the target tubes are mutually assembled by means of welding. The co-sputtering target tubes are selected from at least one of aluminum, copper, nickel, iron, and praseodymium target tubes, and the end target tubes are non-rare earth target tubes or rare earth target tubes. The co-sputtering rare earth rotating target material provided in the embodiments of the present application is applicable to the field of grain boundary diffusion of magnetic material coating film, and can realize that the rare earth target material and the target material of co-sputtering elements such as aluminum and copper adhere to the surface of the magnet by sputtering at the same time, so as to improve the sputtering efficiency, eliminate the preparation of the alloy target material and facilitate the recovery of the residual target. By combining the rare earth target tube with the target tube of co-sputtering elements such as aluminum and copper in the same rotating target material, and controlling the length ratio of the rare earth target material and beneficial target materials such as aluminum and copper, combined with the sputtering process, the accurate control of the rare earth and co-sputtering elements can be achieved, which is helpful for the subsequent grain boundary diffusion. The beneficial technical effects of shortening the grain boundary diffusion time and reducing the diffusion temperature can be achieved while the utilization rate and the sputtering efficiency of the rare earth target material are improved.

It is to be understood that the above-described specific implementations of the application are merely illustrative or explanatory of the principles of the application and are not restrictive of the application. Therefore, any modifications, equivalent replacements, improvements, etc. made without deviating from the spirit and scope of the present application shall be included within the scope of the present application. Furthermore, it is intended that the appended claims cover all such variations and modifications that fall within the scope and boundaries of the appended claims of the present application, or equivalent forms of such scope and boundaries.

What is claimed is:

1. A co-sputtering rare earth rotating target material, comprising a back tube and a plurality of sections of target tubes welded to the outside of the back tube;
wherein the back tube and the plurality of sections of target tubes welded to the outside of the back tube are concentric cylindrical structures;
the plurality of sections of target tubes welded to the outside of the back tube comprise two sections of end target tubes arranged at an axial end of the target material, and a plurality of sections of rare earth target tubes and a plurality of sections of co-sputtering target tubes which are arranged between the two sections of end target tubes and with a target material along an axial middle region; the plurality of sections of rare earth target tubes are spaced apart from the plurality of sections of co-sputtering target tubes, and the target tubes are mutually assembled via welding; and
the co-sputtering target tubes are selected from at least one of aluminum, copper, nickel, iron, and praseodymium target tubes, and the end target tubes are non-rare earth target tubes or rare earth target tubes.

2. The rare earth rotating target material according to claim 1, wherein the rare earth target tube comprises a rotating target tube selected from terbium, dysprosium, holmium, and gadolinium.

3. The rare earth rotating target material according to claim 1, wherein a length of the end target tube is 20-35 mm, lengths of both the rare earth target tube and the co-sputtering target tube are less than or equal to 300 mm, and a length ratio of the rare earth target tube and the co-sputtering target tube arranged in the middle region is 1.3-20.

4. The rare earth rotating target material according to claim 1, wherein a clearance d is left between the mutually assembled target tubes, and a value of the clearance d is 0.1 mm≤d≤ 0.5 mm.

5. The rare earth rotating target material according to claim 1, wherein the co-sputtering target tube is an aluminum target tube or a copper target tube;
when the co-sputtering target tube is an aluminum target tube, the length ratio of the rare earth target tube to the co-sputtering target tube arranged in the middle region is 1.8-3.0;
when the co-sputtering target tube is a copper target tube, the length ratio of the rare earth target tube to the co-sputtering target tube arranged in the middle region is 6.0-10.0.

6. The rare earth rotating target material according to claim 1, wherein outer diameters of two rare earth target tubes adjacent to the end target tubes at both ends of the target material are reduced from an outer diameter OD2 to an outer diameter OD3 from a direction of both ends of the target material to a direction of the middle region, and the outer diameter OD2 is equal to the outer diameter OD1 of the end target tube.

7. A preparation method for the rare earth rotating target material according to claim 1, comprising the following steps:
assembling two sections of end target tubes, a plurality of sections of rare earth target tubes, and a plurality of sections of co-sputtering target tubes, wherein the two sections of end target tubes are arranged at two ends of the target material along the axial direction; the plurality of sections of rare earth target tubes are spaced apart from the plurality of sections of co-sputtering target tubes in the middle region of the target material along the axial direction; and the plurality of sections of rare earth target tubes are spaced apart from the plurality of sections of co-sputtering target tubes;
assembling each target tube and back tube together by welding; and
welding the assembled target tubes and the back tube.

8. A method for co-sputtering using the rare earth rotating target material according to claim 1, comprising the following steps:
arranging the rare earth rotating target material and a magnet on a coating production line;
performing vacuum pumping, pre-sputtering, and then sputtering; and
subjecting the magnet to thermal and temper treatments.

9. The method according to claim 8, wherein the thermal treatment temperature is 600-950° C.; and the thermal treatment time is 5-10 hours.

10. The method according to claim 8, wherein the temper treatment temperature is 400-600° C. and the temper treatment time is 2-6 hours.
